(19) United States
(12) Patent Application Publication
(10) Pub. No.: US 2024/0395790 A1
(43) Pub. Date: Nov. 28, 2024

(54) SEMICONDUCTOR DEVICE

(71) Applicant: Fraunhofer-Gesellschaft zur Förderung der angewandten Forschung e.V., München (DE)

(72) Inventor: Andy HEINIG, Dresden (DE)

(21) Appl. No.: 18/796,849

(22) Filed: Aug. 7, 2024

Related U.S. Application Data
(63) Continuation of application No. PCT/EP2023/053539, filed on Feb. 13, 2023.

(30) Foreign Application Priority Data
Feb. 14, 2022 (EP) 22156634.2

(51) Int. Cl. H01L 25/18; H01L 23/00

(52) U.S. Cl. CPC H01L 25/18; H01L 24/05; H01L 24/08; H01L 2224/05647; H01L 2224/08146; H01L 2924/1425

(57) ABSTRACT

A semiconductor device has: a first circuit layer having at least an integrated circuit; and a second circuit layer having at least a current supply configured to supply the integrated circuit with electrical energy; wherein a second main surface of the first circuit layer is connected to a first or second main surface of the second circuit layer.

### CROSS-REFERENCE TO RELATED APPLICATIONS

This application is a continuation of copending International Application No. PCT/EP2023/053539, filed Feb. 13, 2023, which is incorporated herein by reference in its entirety, and additionally claims priority from European Application No. 22156634.2, filed Feb. 14, 2022, which is incorporated herein by reference in its entirety.

### TECHNICAL FIELD

Embodiments of the present invention relate to a semiconductor device, in particular to one comprising a 3D integration face-to-face current supply. Further embodiments relate to a corresponding manufacturing method.

### BACKGROUND OF THE INVENTION

Up to now, the current supply of an integrated circuitry or, generally of a circuitry or of a 3D stack of circuitries, has been realized by an external current supply, like DC-DC converters, for example, or by an on-chip DC-DC converter. On-chip DC-DC converters may, for example, be located in the same circuit layer or the same 3D stack of circuit layers. In the latest circuit technology, like 3-nm technology, for example, on-chip DC-DC converters can (technically) no longer be realized. The cause of this is that the corresponding transistors do no longer exhibit a sufficient dielectric strength and/or current carrying capacity. Even external DC-DC converters can no longer guarantee the entailed stability of the supply voltage. The cause here:

the supply voltage has been reduced repeatedly over the last years, wherein the allowed deviation from the nominal supply voltage has stayed approximately the same so that the requirements to an overall solution have increased considerably.

However, this can usually no longer be realized using an external current supply since in this case the supply lines become too long.

Consequently, there is need for an improved approach. The object underlying the present invention is providing a current supply for the latest circuitry technologies, like 3-nm technology, for example, which eliminates or minimizes disadvantages with regard to manufacturability and supply voltage stability.

### SUMMARY

According to an embodiment, a semiconductor device may have: a first circuit layer having at least an integrated circuit; and a second circuit layer having at least a current supply configured to supply the integrated circuit with electrical energy; the second circuit layer having a first region having a semiconductor material and at least a second region having a mold material, wherein the first and second regions extend over the width of the first circuit layer; wherein a second main surface of the first circuit layer is connected to a first or second main surface of the second circuit layer; wherein the second circuit layer has one or more vias which extend over the thickness of the second circuit layer and are configured to provide signal contact of the integrated circuit; and wherein the one or more vias extend through a mold material of the second circuit layer, wherein the current supply has a DC-DC converter.

Another embodiment may have a manufacturing method for manufacturing a semiconductor device in accordance with the invention as mentioned above, wherein the manufacturing method has the step of connecting the first circuit layer to the second circuit layer.

Embodiments of the present invention provide a semiconductor device comprising a first circuit layer and a second circuit layer. The first circuit layer comprises at least an integrated circuit, like a memory and/or logic, for example. The second circuit layer comprises at least a current supply configured to supply the integrated circuit with electrical energy. Here, a second main surface of the first circuit layer (like a front side/face, for example) is connected to a first or second main surface (front or back side (face or back) depending on the embodiment) of the second circuit layer.

Embodiments of the present invention are based on the finding that, using novel package technology, like 3D integration, it is possible to manufacture highly compact realizations of different components in a chip stack. In 3D integration, the circuitries are stacked one above the other. The one or more circuits which are provided with the actual logic or memory function are arranged within the first circuit layer, and set up as a 3D stack. For this circuit layer or these circuit layers, a novel manufacturing technology can be used, like 3-nm technology, for example. The respective current supply is arranged in a second circuit layer. Since the two circuit layers are arranged to be directly adjacent to each other, for example by means of bonding or using copper pillar, the line lengths are extremely small so that the voltage stability in correspondence with the application case can be achieved. By using a separate circuit layer, a different manufacturing technology can be used in the first circuit layer, which also favors manufacturability of powerful current supplies. In addition, embodiments of the present invention advantageously provide a voltage supply which is realized directly at the consumer.

In accordance with embodiments, the integrated circuit of the first circuit layer (or, generally, the first circuit layer) is manufactured using a first semiconductor manufacturing technology (like 3-nm technology), wherein the at least one current supply of the second current layer or, generally, the second circuit layer is manufactured using a second semiconductor manufacturing technology. The first semiconductor manufacturing technology differs from the second semiconductor manufacturing technology. In accordance with embodiments, the first semiconductor manufacturing technology may, for example, include 3-nm technology or an improved or further miniaturized semiconductor manufacturing technology.

Subsequently, three exemplary embodiments of 3D integration will be discussed.
In accordance with a first variation, the second circuit layer can be face-to-back coupled to the first circuit layer. Here, the first main surface of the second circuit layer is connected to the second main surface of the first circuit layer.
In accordance with a second variation, the first and second circuit layers can be face-to-face connected. Here, the second main surface of the first circuit layer is connected to the second main surface of the second circuit layer. In these two circuit layers, for example, the materials, in particular semiconductor materials, of the two circuit layers may roughly be exactly so wide that a 3D structure results.
In accordance with a third variation, it would also be conceivable for the second circuit layer to comprise a mold material. Here, for example, the two circuit layers are face-to-face connected with a mold. This means that the second main surfaces of the first and second circuit layers are again connected to each other.

In accordance with embodiments, the connection of the second main surface of the first circuit layer to the first or second main surface of the second circuit layer is a direct connection, a direct bond connection, a bond connection, a connection with a contact pad or a connection with a copper contact pad (or copper pillar). In accordance with embodiments, the second circuit layer covers the (entire) surface of the first circuit layer. In other words, this means that these two circuit layers are of the same size. In accordance with embodiments, the second circuit layer comprises a semiconductor material over the entire width of the first circuit layer. In accordance with other embodiments, the second circuit layer comprises a first region having a semiconductor material and at least a second region having a mold material. Several second regions may also be provided, like laterally next to the semiconductor region. In this case, the first and second regions may, for example, extend over the (entire) width of the first circuit layer. Alternatively, each of the two regions may also have sub-regions so that the entire width is implemented by the first and second regions each having one or more sub-regions, wherein the sub-regions may also be implemented to be different.

In accordance with a further embodiment, the first main surface of the second circuit layer comprises contacts or a contacting sheet if the second main surface serves for connecting to the first circuit layer. Alternatively, the second main surface of the second circuit layer comprises contacts or a contacting sheet if the first main surface serves for contacting the first circuit layer. In accordance with embodiments, the contacts are configured to be connected to an unregulated voltage source. In accordance with embodiments, the current supply is configured to provide, starting from an unregulated voltage applied of an unregulated voltage source, a regulated voltage on the side of the second main surface of the first circuit layer, i.e., depending on the structure, via its first or second main surface in order to supply the integrated circuit correspondingly with electrical energy (current supply).

In accordance with embodiments, the second circuit layer comprises one or more vias which extend over the thickness of the second circuit layer and are configured to provide for signal contact of the integrated circuit. In accordance with embodiments, the one or more vias may extend through the semiconductor material of the second circuit layer or through a mold material of the second circuit layer. This means that these two embodiments advantageously provide for signal contacting of the integrated circuit of the first circuit layer to be performed via that main surface of the second circuit layer facing away from the first circuit layer.

As has been indicated above, each circuit layer may comprise one or more levels so that a 3D-integrated circuit is formed, depending on the circuit layer. In accordance with embodiments, the second main surface of the first circuit layer and/or the second main surface of the second circuit layer may comprise a rewiring sheet and/or a device sheet. Contacting to the other circuit layer, for example, is made via this rewiring sheet.

In accordance with further embodiments, the semiconductor device comprises a further circuit layer which is arranged on a first main surface of the first circuit layer. For example, this further circuit layer may comprise an integrated circuitry, logic and/or memory.

A further embodiment provides a manufacturing method of the semiconductor device discussed before. The manufacturing method comprises the step of connecting the first circuit layer to second circuit layer. In accordance with embodiments, connecting may be done by bonding, direct bonding or producing a contact pad or copper pillar connection. In accordance with embodiments, connecting is performed by means of face-to-back technology or face-to-face technology.

### BRIEF DESCRIPTION OF THE DRAWINGS

Embodiments of the present invention will be discussed below referring to the appended drawings, in which:

FIG. 1 is a schematic illustration of a semiconductor device in sectional view, comprising a face-to-back arrangement, in accordance with embodiments;

FIG. 2 is a schematic illustration of a semiconductor device in sectional view, comprising a face-to-face arrangement, in accordance with another embodiment; and

FIG. 3 is a schematic illustration of a semiconductor device with a mold in sectional view, comprising a face-to-face arrangement, in accordance with a further embodiment.

### DETAILED DESCRIPTION OF THE INVENTION

Before discussing below embodiments of the present invention referring to the appended drawings, it is to be pointed out that equal elements and structures are provided with equal reference numerals so that the description thereof is mutually applicable or interchangeable.

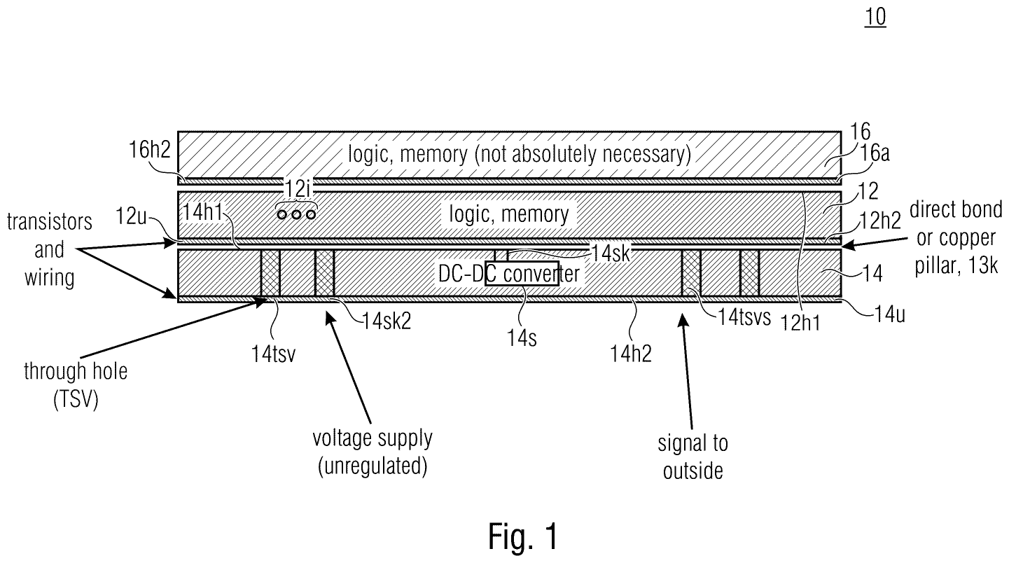

FIG. 1 shows a semiconductor device 10 comprising at least two circuit layers 12 and 14. These two circuit layers are provided one above the other, i.e. directly adjacent to each other or connected to each other or even directly connected to each other. The two circuit layers 12 and 14 may, for example, comprise an identical, similar or, at least, comparable width and together form a chip or semiconductor device 10. Optionally, a third circuit layer 16 may be provided which will not be discussed here in detail in connection with the basic embodiment. The first circuit layer 12 is, for example, the top circuit layer, whereas the circuit layer 14 is the bottom circuit layer. The top circuit layer 12 is connected with its second main surface 12h2, i.e. with its bottom, to the second circuit layer 14. Here, the second main surface 12h2 of the first circuit layer is connected to the first main surface 14h1 of the second surface layer 14. The main surface 12h2 is the front side of the first circuit layer 12, whereas the circuit layer 14h1 can be referred to as backside of the second circuit layer 14. The front side of the front circuit layer 14 is provided with the reference numeral 14h2. The arrangement described results in a so-called face-to-back (front side to back side) arrangement of the two circuit layers 12 and 14, the result being a 3D stack of circuitries.

The two circuit layers 12 and 14 may of course also comprise more sheets of regions, like semiconductor regions, doped regions, insulating regions or conducting regions (metallization sheet), for example, to produce the electrical devices which are provided for the respective circuit layer 12 and 14. The device or the circuit layer 12 comprises, for example, one or more integrated circuits 12i which form a logic or memory, for example. In accordance with embodiments, the entire circuit layer 12 is manufactured by a manufacturing technology, like 3-nm semiconductor manufacturing technology, for example, so that the circuit layer 12 which comprises a common semiconductor material (in different sheets), for example, can be referred to as a device or as a chip.

The circuit layer 14 comprises a current supply 14s, like a DC-DC converter. The current supply 14 serves for supplying the integrated circuit 12i with a correspondingly stabilized voltage. For example, the current supply 14s is electrically coupled to an optional rewiring sheet 12u of the circuit layer 12 via contacts 14sk on the surface 14h1. The result of this are very short line lengths, which is of advantage for the stabilized voltage. By producing the current supply 14s in a separate device or separate circuit layer 14, a different manufacturing technology can be used when compared to the circuit layer 12, for example, an older circuit technology or, generally, a technology which is of advantage for manufacturing devices for current supply.

The embodiment may thus be described in that two circuit layers 12 and 14 are connected to each other by means of a face-to-back arrangement. Direct bond technology (direct bonding or, generally, bonding) can be used for this connection, or also copper pillars or, generally, connection pads or copper pillows can be used.

It is to be mentioned here that, in accordance with embodiments, the current supply 14s may comprise one or more DC-DC converters. Since it is assumed, for example, that the current supply 14s is supplied from the bottom 14h2 (second main surface) with an unregulated voltage, the DC-DC converter 14s can perform voltage regulation such that a highly adjusted voltage is provided with a sufficient electrical energy without great variations. The unregulated voltage may, for example, be applied via the contact terminals 14sk2.

Additionally, in accordance with further embodiments, the circuit layer 14 may comprise one or more through-contactings or vias (tsv), which are, for example, marked by the reference numeral 14tsv. They serve, for example, for making a direct connection (electrical connection) from the second main surface 14h2 to the first main surface 14h1. Here, a signal from outside can be applied to the integrated circuit 12i. Signal vias are referred to by the reference numeral 14tsvs.

In accordance with a further embodiment, a further circuit layer 16 may be arranged on the first main surface 12h1 (top), for example, which in turn is arranged with its bottom 16h2 (second main surface) and, in accordance with embodiments, may comprise an integrated circuit, like a logic or memory (not illustrated), for example. In the embodiments presented here, the bottom 16h2, 14h2 and 12h2 may be characterized in that it comprises a rewiring sheet 12u, 16u or 14u. The rewiring sheet serves for electrically contacting the individual devices in the semiconductor region and may, for example, be implemented as a metallization. Instead of the rewiring sheet, a type of transistor sheet may, of course, also be provided, wherein parts of the transistors may, for example, also be formed in the semiconductor region. The rewiring sheet serves for contacting from outside, for example, as can be seen in particular with regard to the rewiring sheet 14u.

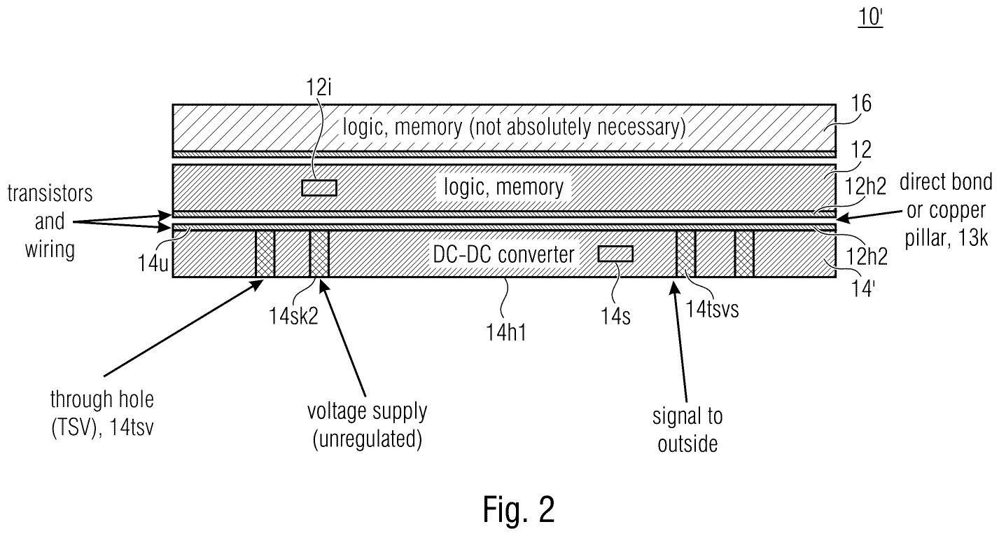

A further embodiment will be discussed below referring to FIG. 2.

FIG. 2 shows a semiconductor device 10′ comprising again two circuit layers 12 and 14′, and an optional circuit layer 16. The circuit layer 12 basically corresponds to the circuit layer 12 from FIG. 1 and comprises the integrated circuit 12i, for example. The circuit layer 12 is connected to the circuit layer 14′ via its second main surface 12h2. The circuit layer 14′ basically is comparable to the circuit layer 14 from FIG. 1 and comprises, for example, also the DC converter 14s as a current supply. In this embodiment, the circuit layer 14′, however, is not connected to the circuit layer 12 with the main surface 14h1, but with the main surface 14h2. As mentioned above, this second main surface 14h2 may, for example, comprise the rewiring sheet 14u.

This arrangement is referred to as face-to-face arrangement. Using this arrangement, the path from the DC-DC converter 14s to the actual circuit 12i is extremely short. Additionally, the DC-DC converter 14s may be manufactured in an older circuit technology. Thus, the system is supplied with an unregulated voltage from the bottom (side of the circuit layer 14), cf. terminals 14sk2, wherein the voltage regulation in the circuitry is performed by the DC-DC converter 14h2. The “normal” signals of the circuitry with the logic and the memory 12i are conducted to the outside via the circuitry 14′ with the DC-DC converter 14s, using the vias 14tsvs.

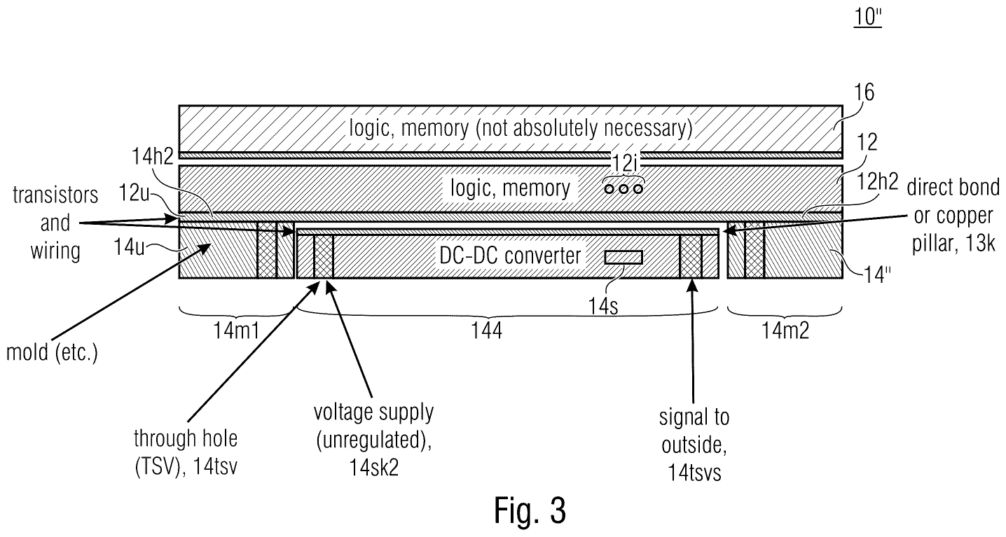

A so-called face-to-face arrangement with a mold is discussed below referring to FIG. 3. FIG. 3 shows the semiconductor arrangement 10″ having the circuit layers 12, 14″ and the optional circuit layer 16.

The circuit layer 14″ is a further development of the circuit layer 14′ and, apart from the semiconductor material or the first material in the region of the voltage supply 14s, comprises a further material. This further material is referred to by the reference numeral 14m1 and 14m2 and may, for example, comprise a mold material. The sheet 14″ in turn is coupled to the second main surface 12h2 of the first circuit layer 12 with its second main surface 14h2.

This means that the embodiment illustrated here provides a so-called face-to-face arrangement with a mold arrangement. The line length from the DC-DC converter to the “normal” circuit 12i still is extremely short. In addition, it is also ensured that the DC-DC converter 14 or the general current supply 14s can be manufactured using an older circuit technology or an adjusted circuit technology.

It is to be pointed out here that both the semiconductor device 10′ from FIG. 2 and the semiconductor device 10″ from FIG. 3 may also comprise the further features “vias 14tsv or 14tsvs” and “voltage contacts 14sk2”. As can be recognized from the embodiment in FIG. 3, the vias 14tsv may extend in the mold material 14m1 and 14m2, wherein an extension through the semiconductor material 14h would of course also be conceivable. The voltage supply vias, cf. contact 14sk2, for example, extend through the semiconductor material 14h up to the rewiring sheet 14u so that the unregulated voltage of the current supply 14s is provided via this rewiring sheet 14u, the current supply 14s correspondingly regulating the voltage.

It is to be mentioned that in the vias 14tsv and 14tsvs which extend from the mold material 14m1 and 14m2, the vias 14tsv and 14tsvs project to the rewiring sheet 12u, whereas the vias 12sk2 which extend through the semiconductor material 14h project to the rewiring sheet 14u. In the embodiment of FIG. 2, all the vias extend, for example, to the rewiring sheet 14u (cf. is 14tsv, 14tsvs, 14sk2).

In accordance with an embodiment, the vias 14tsv and 14tsvs are used in the mold region 14m1 and 14m2 for signal conducting (control signal for the logic/memory), whereas the vias 14sk2 serve for conducting a current/voltage signal. An external current or voltage signal for the current supply 14s can thus be provided via these vias 14sk2. In accordance with embodiments, contacts are provided on the main surface 14h1 (facing away from the circuit layer 12), i.e. in the region 14m1 and 14m2 or region 14h. The contacts in the region 14h serve for current/voltage supply. The contacts in the region 14m1 and 14m2 serve for coupling a signal. It is of advantage here for the signal to be conducted through the mold material and thus be spaced apart as far as possible from interfering influences from the chip which accommodates the current supply. The insulating properties of the mold material also have a positive technical effect.

In all the above embodiments from FIGS. 1 to 3, the two circuit layers 12 and 14 can be connected by means of direct bonding or copper pillars. A copper pillar is provided with the reference numeral 13k. However, it is also to be pointed out here that other ways of connection would also be feasible.

It is common to all the embodiments that very compact realizations for different components in a chip stack are made possible by the novel package technology of 3D integration. In 3D integration, circuitries are stacked one above the other. In this case, this is one or more of the circuitries which are provided with the actual (logic or memory) function and set up as a 3D stack. External components bearing different requirements, like voltage supply 14s, for example, can be transferred to a further circuit layer.

It is to be pointed out here that the above embodiment has always assumed two or three circuit layers, wherein more circuit layers (i.e. more than three) would also be feasible, of course. In particular, the optional circuit layers 16 may also be arranged to be rotated relative to the other circuit layers 12 and 14 (or 14′ or 14″). In the above embodiments, it was assumed that the second circuit layer 14 either to the sheet 14h1 or to the sheet 14h2 (see circuit setup 10′ and 10″). On the side of the first circuit layer 12, the main surface 12h2 is always used. In accordance with further embodiments, coupling to the second circuit layer 14 via the main surface 12h1 would also be conceivable, wherein the connection via the main surface 12h2 is of advantage in that the rewiring sheet 12u is provided here, via which the supply voltage can easily be fed to the integrated circuits 12i.

Applications of 3D integration mentioned above are semiconductor devices which may comprise, at least in regions, a semiconductor material, like a silicon or gallium arsenide, for example. As regards their focus of function, the applications are not restricted, i.e. any devices, both memory devices or processors (logic), are potential fields of application for 3D integration.

Further embodiments relate to a manufacturing method of the embodiments 10, 10′, 10″ discussed before. The manufacturing method comprises the central step of connecting the first and the second circuit layer 12 and 14 or 12 and 14′ or 12 and 14″, i.e. using face-to-back technology, face-to-face technology or face-to-face technology, including mold. As discussed before, connecting may be done by means of contact pads or copper pillars, but also using bonding or direct bonding.

Even when having discussed embodiments in particular in connection with an apparatus (semiconductor device, 3D sheet stack or chip), it is to be pointed out that the explanations of individual product features may at the same time also represent explanations of the corresponding method steps. Vice versa, the explanation of a method step may also be considered to be an explanation of a product step. The scope of protection is defined by the appended claims.

1. A semiconductor device comprising:
a first circuit layer comprising at least an integrated circuit; and
a second circuit layer comprising at least a current supply configured to supply the integrated circuit with electrical energy; the second circuit layer comprising a first region comprising a semiconductor material and at least a second region comprising a mold material, wherein the first and second regions extend over the width of the first circuit layer;
wherein a second main surface of the first circuit layer is connected to a first or second main surface of the second circuit layer;
wherein the second circuit layer comprises one or more vias which extend over the thickness of the second circuit layer and are configured to provide signal contact of the integrated circuit; and wherein the one or more vias extend through a mold material of the second circuit layer,
wherein the current supply comprises a DC-DC converter.

2. The semiconductor device in accordance with claim 1, wherein the connection of the second main surface of the first circuit layer to the first or second main surface of the second circuit layer comprises a direct connection, a direct bond connection, a bond connection, a connection with a contacting or a connection with a copper contacting.

3. The semiconductor device in accordance with claim 1, wherein the integrated circuit comprises logic/or a memory.

4. The semiconductor device in accordance with claim 1, wherein the second circuit layer covers the surface of the first circuit layer.

5. The semiconductor device in accordance with claim 1, wherein the first main surface of the second circuit layer comprises contacts when the second main surface serves for connecting to the first circuit layer, or wherein the second main surface of the second circuit layer comprises contacts when the first main surface serves for contacting with the first circuit layer.

6. The semiconductor device in accordance with claim 1,
wherein the semiconductor device comprises contacts on a main surface of the second circuit layer facing away from the first circuit layer,
wherein the contacts are arranged in the first region and are configured to conduct a current/voltage signal for voltage supply, and/or wherein the contacts are arranged in the second region and are configured to conduct a control signal.

7. The semiconductor device in accordance with claim 1, wherein the current supply is configured to provide, starting from an unregulated voltage applied of an unregulated voltage source, a regulated voltage on the side of the second main surface of the first circuit layer for current supply for the integrated circuit; and/or
wherein the contacts are configured to be connected to an unregulated voltage source.

8. The semiconductor device in accordance with claim 1,
wherein the second circuit layer comprises one or more further vias which extend through the first region and are configured to transport a current/voltage signal to the current supply.

9. The semiconductor device in accordance with claim 1, wherein the second main surface of the first circuit layer and/or the second main surface of the second circuit layer comprise a rewiring sheet and/or a device sheet.

10. The semiconductor device in accordance with claim 1, wherein a further circuit layer comprising an integrated circuit, logic and/or memory is arranged on a first main surface of the first circuit layer.

11. The semiconductor device in accordance with claim 1, wherein the integrated circuit of the first circuit layer is manufactured using a first semiconductor manufacturing technology, and wherein the at least one current supply of the second circuit layer is manufactured using a second semiconductor manufacturing technology; and
wherein the first manufacturing technology differs from the second manufacturing technology, and/or wherein the first semiconductor manufacturing technology comprises 3-nm or better technology.

12. A manufacturing method for manufacturing a semiconductor device in accordance with claim 1, wherein the manufacturing method comprises connecting the first circuit layer to the second circuit layer.

13. The manufacturing method in accordance with claim 12, wherein connecting is performed by bonding, direct bonding or manufacturing a contacting connection or copper contacting connection.

14. The manufacturing method in accordance with claim 12, wherein connecting is performed by means of face-to-back technology or face-to-face technology.

15. A manufacturing method for manufacturing a semiconductor device in accordance with claim 2, wherein the manufacturing method comprises connecting the first circuit layer to the second circuit layer.

16. A manufacturing method for manufacturing a semiconductor device in accordance with claim 3, wherein the manufacturing method comprises connecting the first circuit layer to the second circuit layer.

17. A manufacturing method for manufacturing a semiconductor device in accordance with claim 4, wherein the manufacturing method comprises connecting the first circuit layer to the second circuit layer.

18. A manufacturing method for manufacturing a semiconductor device in accordance with claim 5, wherein the manufacturing method comprises connecting the first circuit layer to the second circuit layer.

19. A manufacturing method for manufacturing a semiconductor device in accordance with claim 6, wherein the manufacturing method comprises connecting the first circuit layer to the second circuit layer.

20. A manufacturing method for manufacturing a semiconductor device in accordance with claim 7, wherein the manufacturing method comprises connecting the first circuit layer to the second circuit layer.

21. A manufacturing method for manufacturing a semiconductor device in accordance with claim 8, wherein the manufacturing method comprises connecting the first circuit layer to the second circuit layer.

22. A manufacturing method for manufacturing a semiconductor device in accordance with claim 9, wherein the manufacturing method comprises connecting the first circuit layer to the second circuit layer.

23. A manufacturing method for manufacturing a semiconductor device in accordance with claim 10, wherein the manufacturing method comprises connecting the first circuit layer to the second circuit layer.

24. A manufacturing method for manufacturing a semiconductor device in accordance with claim 11, wherein the manufacturing method comprises connecting the first circuit layer to the second circuit layer.
